(19) United States
(12) Patent Application Publication
(10) Pub. No.: US 2014/0285262 A1
(43) Pub. Date: Sep. 25, 2014

(54) CONTROL DEVICE OF POWER AMPLIFIER AND METHOD OF CONTROLLING POWER AMPLIFIER

(71) Applicant: FUJITSU LIMITED, Kawasaki-shi (JP)

(72) Inventors: Masakazu KOJIMA, Hiratsuka (JP); Shigekazu Kimura, Yokohama (JP); Takeshi Takano, Yokohama (JP); Toru Maniwa, Setagaya (JP); Ken Tamanoi, Yokohama (JP)

(73) Assignee: FUJITSU LIMITED, Kawasaki-shi (JP)

(21) Appl. No.: 14/091,144

(22) Filed: Nov. 26, 2013

(30) Foreign Application Priority Data
Mar. 19, 2013 (JP) 2013-056676

(51) Int. Cl. H03F 1/56

(52) U.S. Cl. CPC H03F 1/56
USPC 330/127

(57) ABSTRACT

A control device of a power amplifier includes: a limiter configured to limit a level of an input signal to the power amplifier; and a control unit configured to, when the limiter operates, make an operation voltage of the power amplifier invariable and control load of an output matching circuit of the power amplifier based on an amplitude of the input signal, and, when the limiter does not operate, to make the load of the output matching circuit invariable and control the operation voltage of the power amplifier.

### CROSS-REFERENCE TO RELATED APPLICATION

This application is based upon and claims the benefit of priority of the prior Japanese Patent Application No. 2013-056676, filed on Mar. 19, 2013, the entire contents of which are incorporated herein by reference.

### FIELD

The embodiments discussed herein are related to a device and a method of controlling a power amplifier.

### BACKGROUND

In wireless communication terminals, such as a mobile telephone, and wireless devices, such as a mobile communication base station device, there is a demand for an amplifier that is excellent in power saving properties and also has less distortion. A power amplifier in a transmitter is used at an output level of good linearity with sufficient back off from a saturated output to satisfy distortion performance.

Related techniques are disclosed in Japanese Laid-open Patent Publication Nos. 2011-244070, 2008-124947, 2011-229122, 2006-93896, and 2009-253809.

### SUMMARY

According to an aspect of the embodiments, a control device of a power amplifier includes: a limiter configured to limit a level of an input signal to the power amplifier; and a control unit configured to, when the limiter operates, make an operation voltage of the power amplifier invariable and control load of an output matching circuit of the power amplifier based on an amplitude of the input signal, and, when the limiter does not operate, to make the load of the output matching circuit invariable and control the operation voltage of the power amplifier.

The object and advantages of the invention will be realized and attained by means of the elements and combinations particularly pointed out in the claims.

It is to be understood that both the foregoing general description and the following detailed description are exemplary and explanatory and are not restrictive of the invention, as claimed.

### BRIEF DESCRIPTION OF DRAWINGS

FIG. 1 illustrates an example of input/output characteristics and efficiency characteristics of a power amplifier;

FIG. 2A illustrates an example of a Smith chart of a power amplifier;

FIG. 2B illustrates an example of an LM power amplifier;

FIG. 3A illustrates an example of a DVC power amplifier;

FIG. 3B illustrates an example of efficiency characteristics;

FIG. 4 illustrates an example of efficiency characteristics;

FIG. 5 illustrates an example of a Smith chart of a power amplifier;

FIGS. 6A and 6B illustrate an example of efficiency characteristics;

FIG. 7 illustrates an example of efficiency characteristics;

FIG. 8 illustrates an example of a wireless device;

FIG. 9 illustrates an example of a power amplifier;

FIG. 10 illustrates an example of input/output characteristics of a power amplifier;

FIG. 11 illustrates an example of input/output characteristics of a power amplifier;

FIG. 12 illustrates an example of a Smith chart of load control;

FIG. 13 illustrates an example of drain voltage control;

FIG. 14 illustrates an example of efficiency characteristics of a PA;

FIG. 15 illustrates an example of efficiency characteristics of a PA;

FIG. 16 illustrates an example of a Smith chart;

FIG. 17 illustrates an example of a power amplifier;

FIG. 18 illustrates an example of a power amplifier;

FIG. 19 illustrates an example of power control;

FIG. 20 illustrates an example of power control;

FIG. 21 illustrates an example of a power amplifier;

FIG. 22 illustrates an example of current control;

FIG. 23 illustrates an example of a power amplifier;

FIG. 24 illustrates an example of voltage control;

FIG. 25 illustrates an example of a power amplifier; and

FIG. 26 illustrates an example of voltage control.

### DESCRIPTION OF EMBODIMENTS

Use at an output level of good linearity corresponds to use of a power amplifier in a state of poor power efficiency, which increases power consumption.

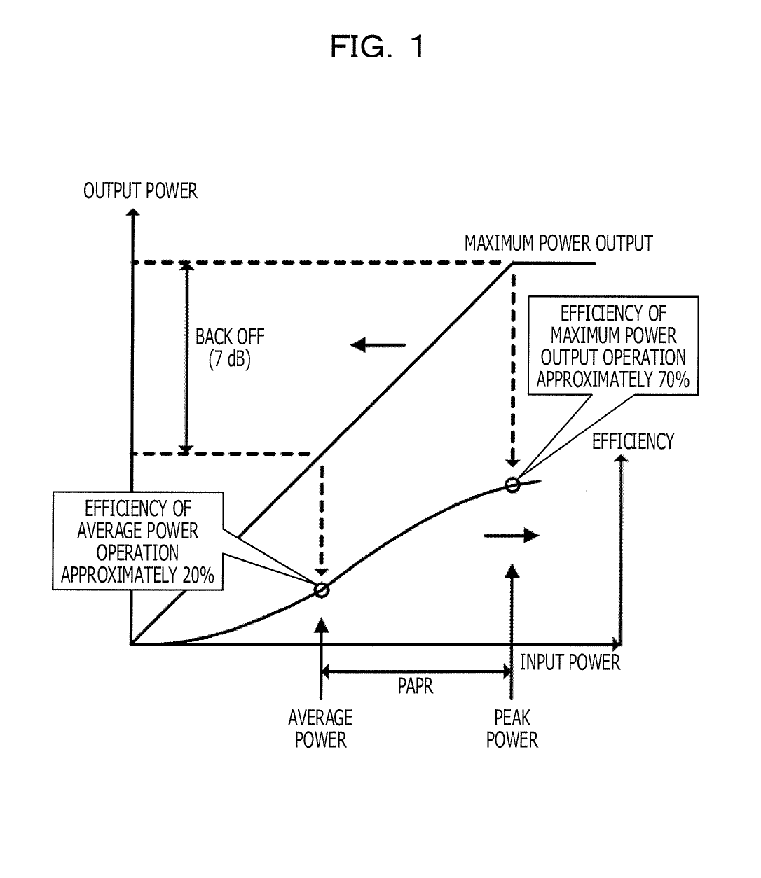

FIG. 1 illustrates an example of input/output characteristics and efficiency characteristics of a power amplifier. In a case that a power amplifier is excited by a sine wave, as illustrated in FIG. 1, for example, maximum efficiency is obtained at maximum power output and the efficiency is rapidly lowered with a decrease of amplitude (level) of an input signal from the maximum power output.

For example, in a case of amplifying a signal with a large peak-to-average power ratio (PAPR) in orthogonal frequency division multiplex (OFDM) used for a mobile communication system, large back off is desired for the power amplifier and the power efficiency (average efficiency) may be lowered.

Table below indicates relationship of average efficiencies of a power amplifier used for global system for mobile communications® (GSM), wideband code division multiple access (WCDMA), and long term evolution (LTE).

TABLE

| System | Efficiency |
|---|---|
| GSM | Approximately 50% |
| WCDMA | Approximately 40% |
| LTE | Approximately 25% |

As illustrated in Table, in a power amplifier that amplifies an OFDM signal of LTE, the power efficiency is significantly low compared with the efficiency with GSM or WCDMA. In order to improve efficiency of a power amplifier for a signal with a large PAPR, load modulation (LM) system or drain voltage control (DVC) system may be employed.

(1) Load Modulation (LM) System

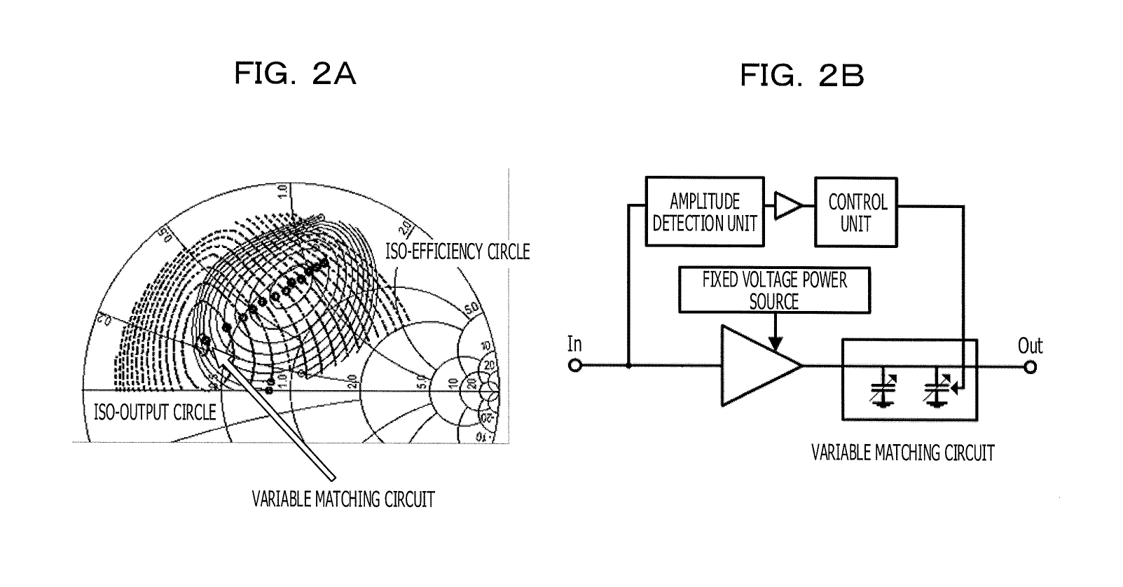

In a power amplifier, load impedance to obtain a maximum output and load impedance to obtain maximum efficiency are different depending on input power. FIG. 2A illustrates an example of a Smith chart of a power amplifier.

In FIG. 2A, an “iso-output circle” represents a contour line of load in which an output of a power amplifier becomes less as going away from the center, and an “iso-efficiency circle” represents a contour line of load in which average efficiency of a power amplifier becomes less as going away from the center.

In FIG. 2A, when carrying out control to appropriately select load for an envelope (amplitude) of an input signal, a power amplifier operates at saturated output power. This may be referred to as load modulation (LM) system.

FIG. 2B illustrates an example of an LM power amplifier. The power amplifier illustrated in FIG. 2B is provided with a power amp (PA), a fixed voltage source, an amplitude detection unit, a control unit, and a (variable) matching circuit. The PA amplifies an input signal based on a fixed voltage from the fixed voltage source. The amplitude detection unit detects an envelope (amplitude) of an input signal. The control unit controls a variable control circuit (load) in accordance with the envelope detected by the amplitude detection unit, thereby operating the PA at the saturated output power.

(2) Drain Voltage Control (DVC) System

In a power amplifier, as a higher drain voltage is set, the saturated power also rises. Therefore, when an envelope (amplitude) of an input signal is appropriately controlled for the drain voltage, the power amplifier operates at the saturated output power. This may be referred to as DVC system.

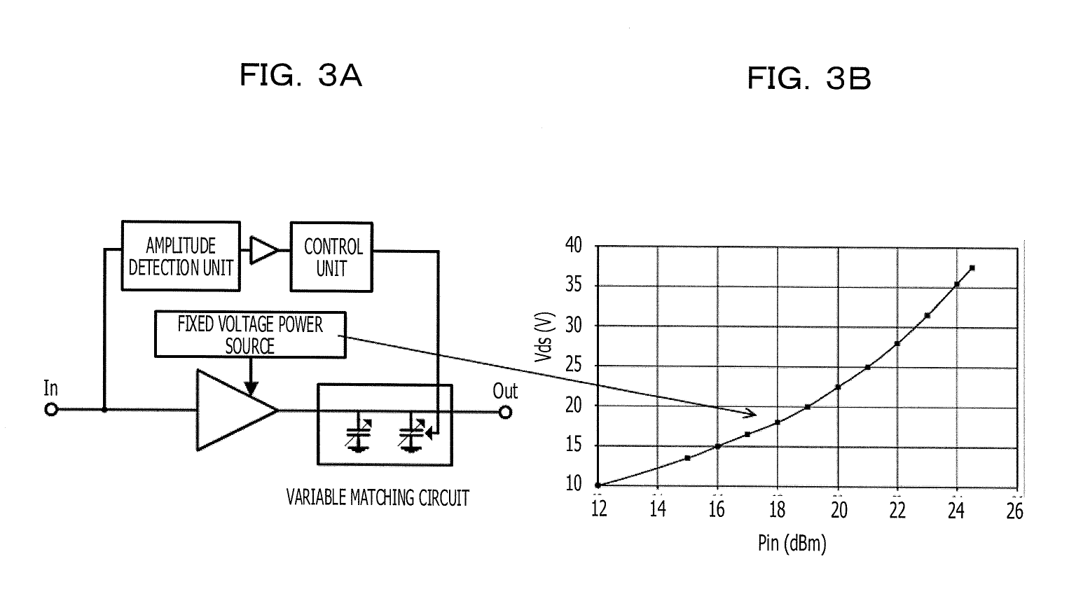

FIG. 3A illustrates an example of a DVC power amplifier. The power amplifier illustrated in FIG. 3A is provided with a power amp (PA), a variable voltage power source, an amplitude detection unit, a control unit, and a (fixed) matching circuit. The amplitude detection unit detects an envelope (amplitude) of an input signal. The control unit controls the variable voltage power source in accordance with the envelope detected by the amplitude detection unit, thereby controlling the drain voltage of the PA. FIG. 3B illustrates an example of efficiency characteristics. A drain voltage Vds is controlled relative to the envelope of the input signal as illustrated in FIG. 3B, thereby operating the PA at the saturated output power.

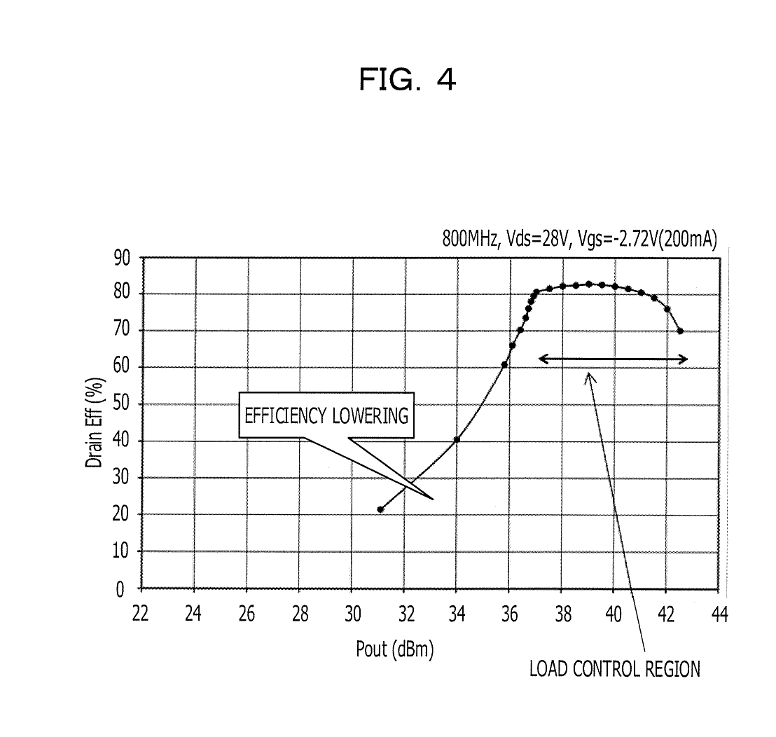

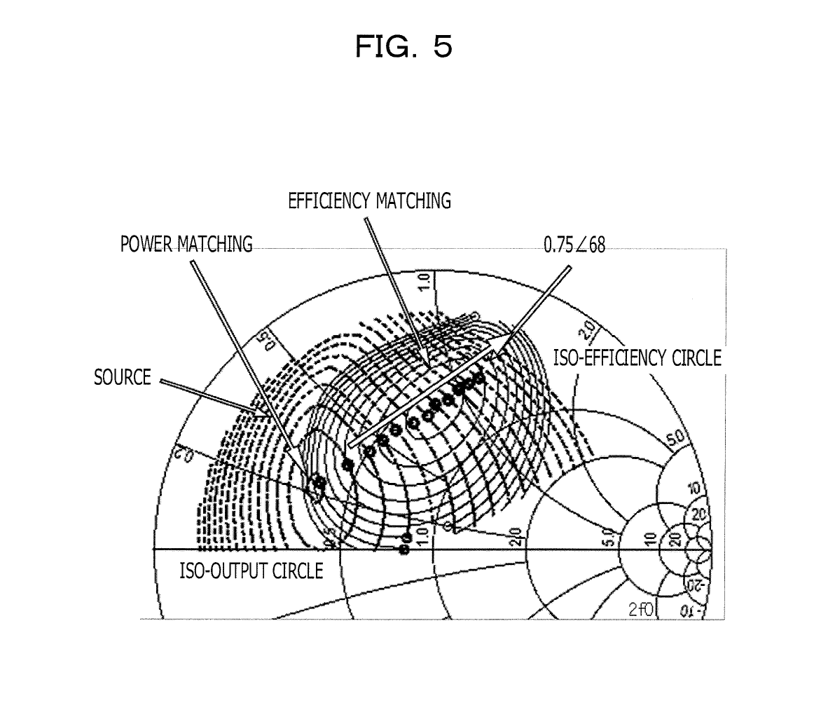

FIG. 4 illustrates an example of efficiency characteristics. FIG. 5 illustrates an example of a Smith chart of a power amplifier. In a power amplifier used for a wireless device, such as a wireless base station, as a locus indicated by an arrow in FIG. 5, even when the load is controlled in accordance with an input signal using LM, the high efficiency region is approximately 6 dB from the saturated output power as illustrated in FIG. 4, for example, and the efficiency may be degraded in small signal regions other than the high efficiency region.

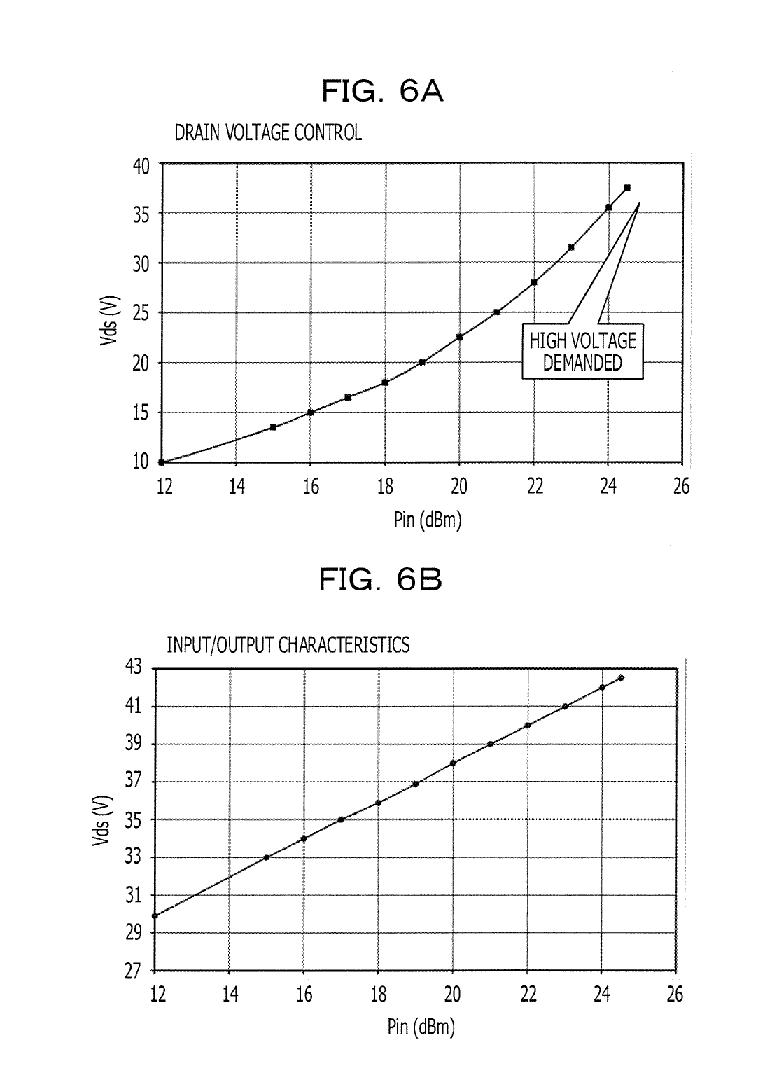

FIGS. 6A and 6B illustrate an example of efficiency characteristics. When the drain voltage Vds is controlled as illustrated in FIG. 6A, for example, to make the input/output characteristics of the PA linear as illustrated in FIG. 6B, for example, using DVC system, a high voltage (high current) is desired for the drain voltage Vds.

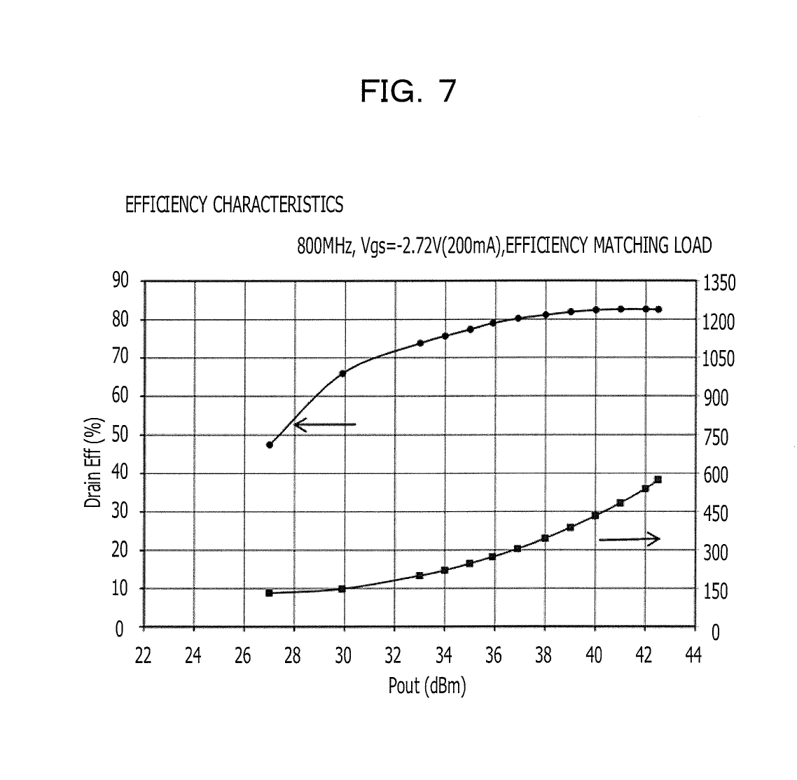

Therefore, in order to operate the PA at the saturated output power, high speed power source control at a high voltage and a high current is desired. FIG. 7 illustrates an example of efficiency characteristics. In FIG. 7, respective characteristics of a drain current Ids (mA: right side vertical axis) and average efficiency Drain Eff (%: left side vertical axis) relative to output power Pout of the PA (dBm: horizontal axis) are illustrated.

In FIG. 7, a trace on the lower side represents a trace of the drain current Ids, and a trace on the upper side represents a trace of the average efficiency Drain Eff. As illustrated in FIG. 7, trying to control output power within 6 dB, for example, from the saturated output power of the PA, high speed power source control at a high voltage and a high current is desired for the drain of the PA.

In the drawings mentioned below, sections with an identical reference numeral represent identical or similar sections unless otherwise specified.

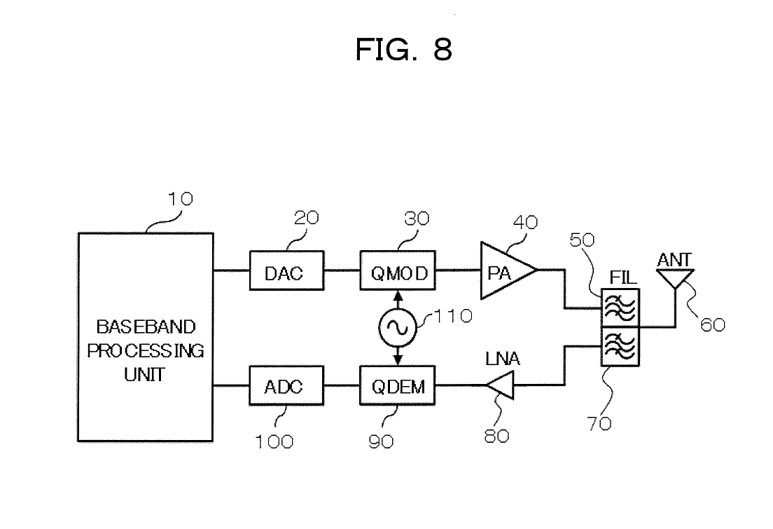

FIG. 8 illustrates an example of a wireless device. The wireless device may be a wireless base station, a mobile station, or the like. The wireless device illustrated in FIG. 8 includes a baseband processing unit 10, a digital to analog converter (DAC) 20, a quadrature modulation unit (QMOD) 30, a power amplifier (PA) 40, a transmission filter 50, a transmitting and receiving antenna 60, a reception filter 70, a low noise amplifier (LNA) 80, a quadrature demodulation unit (QDEM) 90, an analog to digital converter (ADC) 100, and a local oscillator 110.

The baseband processing unit 10 carries out baseband signal processing of a transmission digital signal and a received digital signal.

The DAC 20 converts the transmission digital signal to an analog signal.

The QMOD 30 quadrature up-converts an analog signal converted by the DAC 20 by modulating, for example, QAM modulating the analog signal using a carrier signal input from the local oscillator 110 to obtain a transmission wireless signal.

The PA 40 amplifies the transmission wireless signal obtained by the quadrature modulation in the QMOD 30 to a certain transmission output level.

The transmission filter 50 may be a bandpass filter to remove noise components and the like in the transmission wireless signal amplified by the PA 40.

The transmitting and receiving antenna 60 emits the wireless signal that has passed through the transmission filter 50 in a space towards a wireless device, which is the other end of communication, for example, a base station, a mobile station or the like, while the transmitting and receiving antenna 60 receives a wireless signal emitted in a space from a wireless device, which is the other end of communication.

The reception filter 70 may be a bandpass filter to remove noise components in the wireless signal received by the transmitting and receiving antenna 60.

The LNA 80 amplifies the received wireless signal that has passed through the reception filter 70 to a certain reception level.

The QDEM 90 down-converts the received wireless signal, which is amplified by the LNA 80, by quadrature modulating, for example, QAM modulating using a carrier signal input from the local oscillator 110 to obtain a reception wireless signal.

The ADC 100 converts the reception baseband signal (analog signal) obtained by the quadrature demodulation in the QDEM 90 to a digital signal to input the converted signal to the baseband processing unit 10.

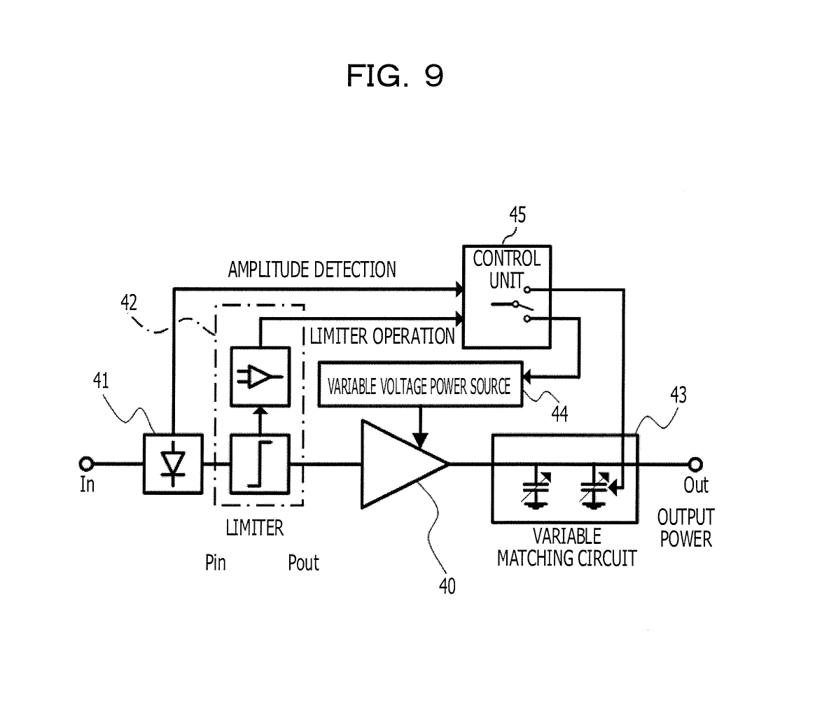

FIG. 9 illustrates an example of a power amplifier. As illustrated in FIG. 9, prior to (on the input side of) the PA 40, an amplitude detection unit 41 and a limiter function unit (hereinafter, may also be referred to simply as a “limiter”) 42 are provided. Following (on the output side of) the PA 40, an output matching circuit 43 with variable load (hereinafter, may also be referred to as a “variable matching circuit”) is provided.

The wireless device is provided with a variable voltage source 44 to give a variable drain voltage to the PA 40 and a control unit 45 to selectively control one of the variable voltage source 44 (drain voltage of the PA 40) and the variable matching circuit (load) 43. The amplitude detection unit 41, the limiter 42, and the control unit 45 may be examples of a control device of the PA 40.

The amplitude detection unit 41 detects an envelope (amplitude) of an input signal, for example, a quadrature modulation signal input from the QMOD 30 by, for example, envelope curve detection. Envelope curve information as a result of the detection is given to the control unit 45.

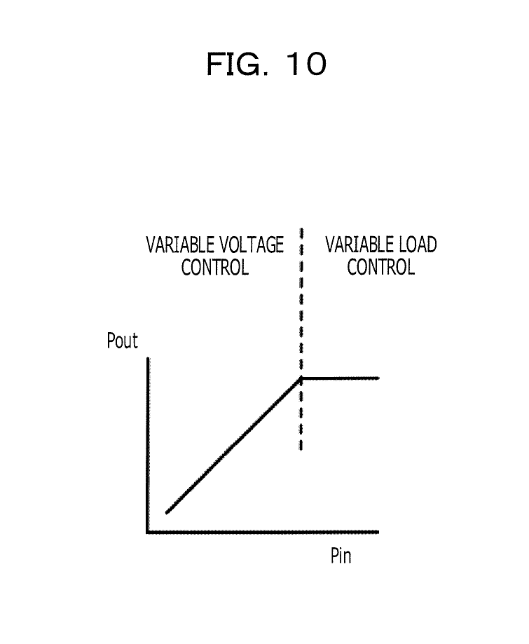

FIG. 10 illustrates an example of input/output characteristics of a power amplifier. As illustrated in FIG. 10, the limiter 42 limits a level of the input signal to the PA 40 at a limiter level (threshold) or lower. In a case that the input signal level reaches the limiter level (a case that a limiter function operates), the limiter function unit 42 gives a signal indicating the situation (hereinafter, may be referred to as “limiter operation notification”) to the control unit 45.

The control unit 45 selectively controls one of the variable voltage source 44 (drain voltage of the PA 40) and the variable matching circuit (load) 43 in accordance with presence of limiter operation notification from the limiter function unit 42. Control of a drain voltage may be referred to as “variable voltage control (DVC mode)”, and control of a variable matching circuit (load) may be referred to as “variable load control (LM control mode)”.

For example, as illustrated in FIG. 10, in a case that the input signal level reaches the limiter level by the limiter operation notification and the limiter function operates (during operation of the limiter), the control unit 45 performs the variable load control. In a case that the input signal level does not reach the limiter level (during non-operation of the limiter), the control unit 45 performs the variable voltage control.

In the variable load (LM) control mode, the variable matching circuit (load) 43 is controlled in accordance with an envelope (envelope curve information) of an input signal from the amplitude detection unit 41 in a state that the operating drain voltage of the PA 40 is assumed to be invariable and also that the input signal level is invariable by being limited by the limiter function.

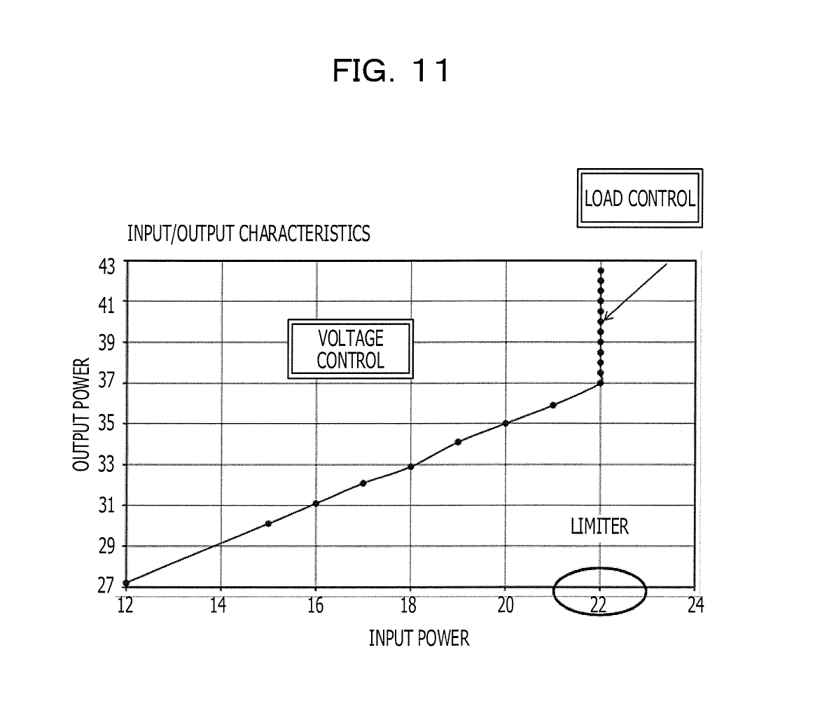

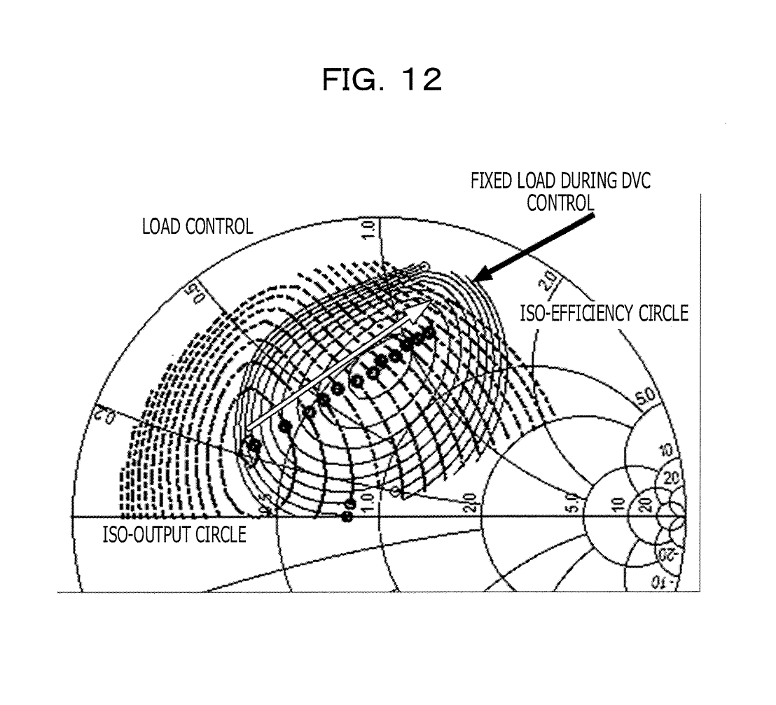

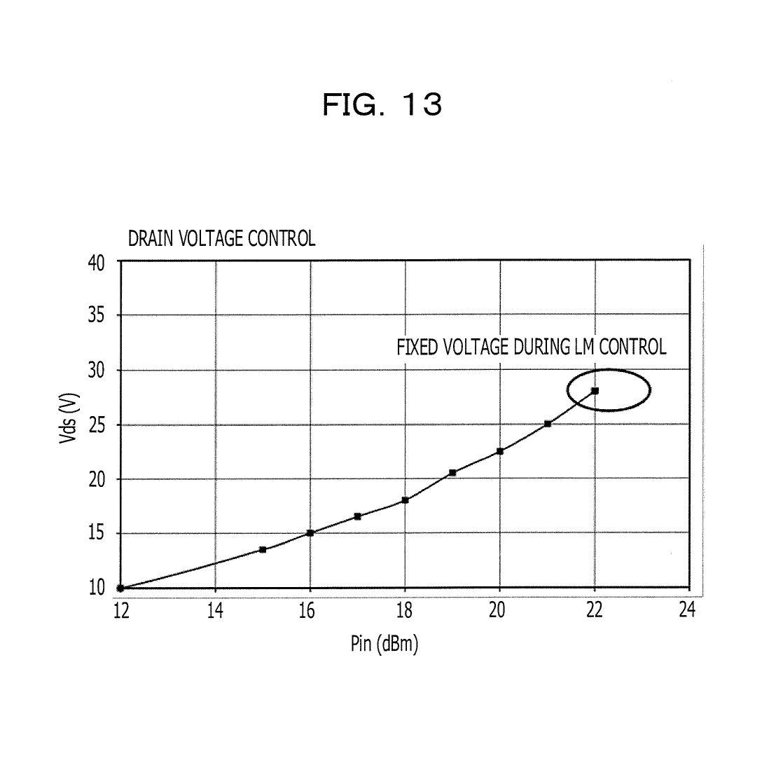

FIG. 11 illustrates an example of input/output characteristics of a power amplifier. FIG. 12 illustrates an example of a Smith chart of load control. FIG. 13 illustrates an example of drain voltage control. For example, in the control unit 45, in the Smith chart illustrated in FIG. 12, the load is variably controlled so as to draw a locus along a direction of leaving away from the center of iso-output circles and also towards the center of iso-efficiency curves, for example, a direction of increasing the power efficiency of the PA 40 with a decrease of the output power of the PA 40. Therefore, the control unit 45 may control output power within, for example, 6 dB from the saturated output power of the PA 40.

In the variable voltage control (DVC) mode, the control unit 45 fixes load 43 to the load at the minimum power and variably controls the drain voltage of the PA 40 in accordance with an envelope of an input signal by the amplitude detection unit 41. At this time, the control unit 45 controls the drain voltage so as to make the input/output characteristics of the PA 40 linear as illustrated in FIG. 13, for example.

In FIG. 13, linear control is performed in the input power region from 12 dBm to 22 dBm, for example, whereas the drain voltage is fixed to perform LM control illustrated in FIG. 12 in the input power region of 22 dBm or more. For example, the value of 22 dBm may be one example of a limiter level (threshold).

By the control based on FIGS. 12 and 13, the input/output characteristics of the PA 40 may be the characteristics illustrated in FIG. 11. For example, DVC may be performed in the input power region (range) from 12 dBm to 22 dBm, and LM control may be performed in the input power range exceeding 22 dBm.

The PA 40 is dynamically controlled relative to an envelope of an input signal. For example, LM control is performed at a fixed voltage in a high output power region of the PA 40, whereas DVC is performed at fixed load in a low output power region, and thus the power efficiency of the PA may be improved in a system with a large PAPR.

For example, the average efficiency of the PA 40 may be improved by appropriately selecting load, in a region of relatively large output power of the PA 40, and a drain voltage of the PA 40, in a region of relatively small output power of the PA 40 relative to an envelope of an input signal of the PA 40.

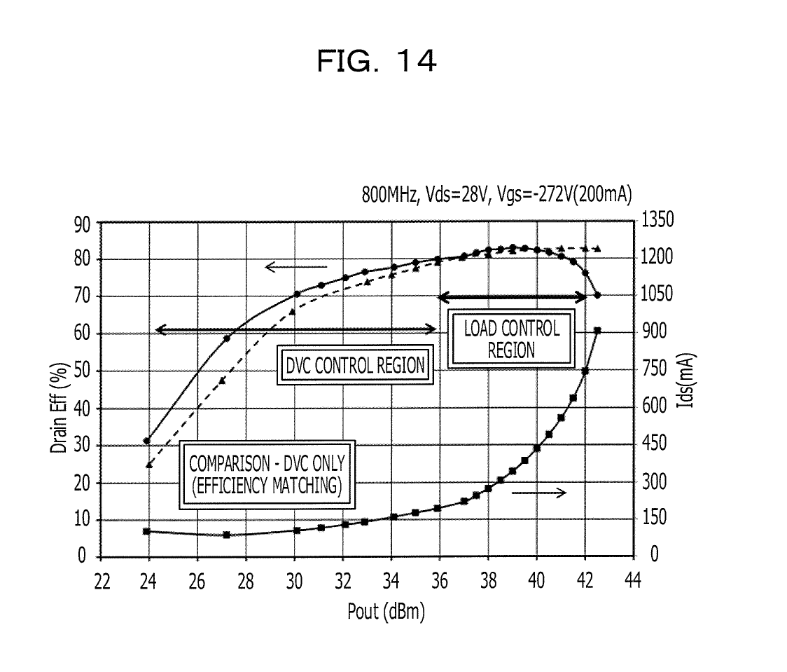

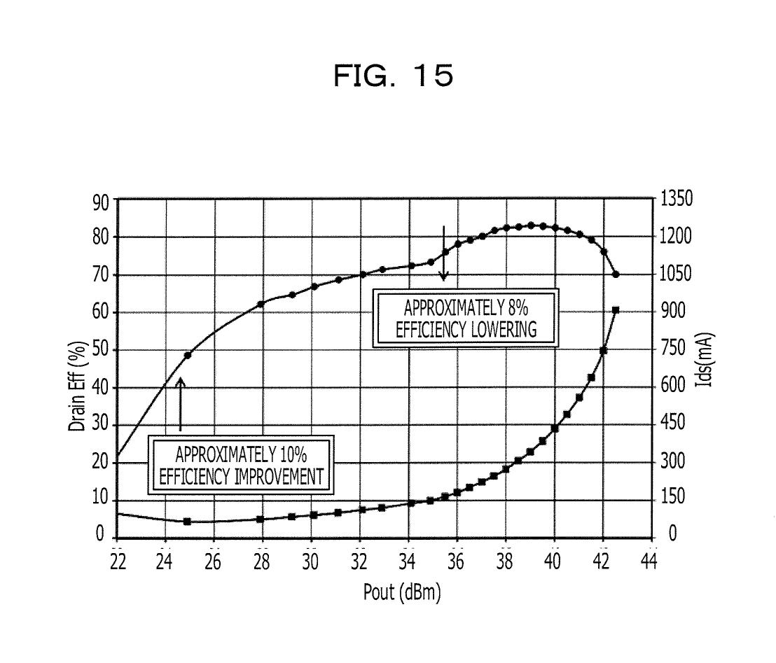

FIGS. 14 and 15 illustrate an example of efficiency characteristics of a PA. As illustrated in FIG. 14, even a signal with a large PAPR, such as an OFDM signal, may obtain highly efficient characteristics. For example, average efficiency of 70% or more may be obtained in a 12 dB dynamic range of output power from 30 dBm to 42 dBm.

FIG. 14 illustrates efficiency characteristics in a case of switching at the output power of 37 dBm between LM control and DVC. FIG. 15 illustrates efficiency characteristics in a case of switching at the output power of 35 dBm between LM control and DVC.

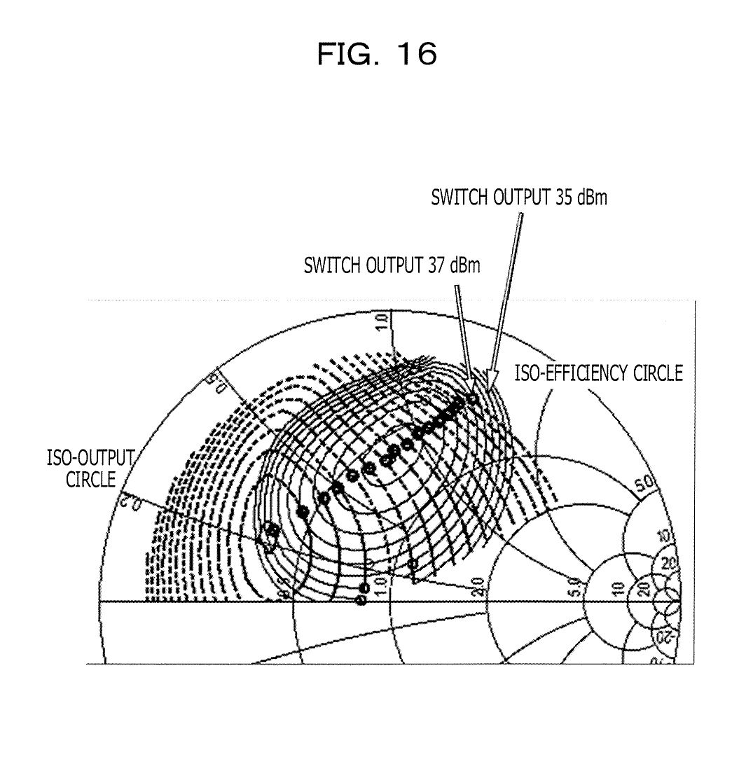

FIG. 16 illustrates an example of a Smith chart. As illustrated in FIG. 16, in the switching at the output power of 35 dBm, the load impedance is at a lower efficiency point of iso-efficiency circles. Therefore, as illustrated in FIG. 15, a decrease in efficiency of approximately 8% from the maximum efficiency close to the output power of 35 dBm is found. For example, the efficiency characteristics may be different depending on the load in which LM control and DVC are switched.

Compared with a case that only DVC is applied among DVC and LM control (efficiency characteristics indicated by a dotted line in FIG. 14), the efficiency during low output power is improved approximately 10%. The effect may be greater than simple combination of DVC and LM control.

While the PA has load characteristics varying in accordance with an input signal level, the PA is equipped with a limiter function unit. Therefore, control is carried out in a state of load characteristics of reduced variation by invariably limiting the input signal level, and the controllability may be improved. In a case of simply combining LM control and DVC, the load characteristics vary in accordance with the input signal level, so that the optimal load and voltage may not be selected.

Fixed drain voltage and load control is performed in a case that the input signal level exceeds the limiter level, and fixed load and drain voltage control is performed in a case that the input signal level is at the limiter level or lower, and thus the controllability may be improved.

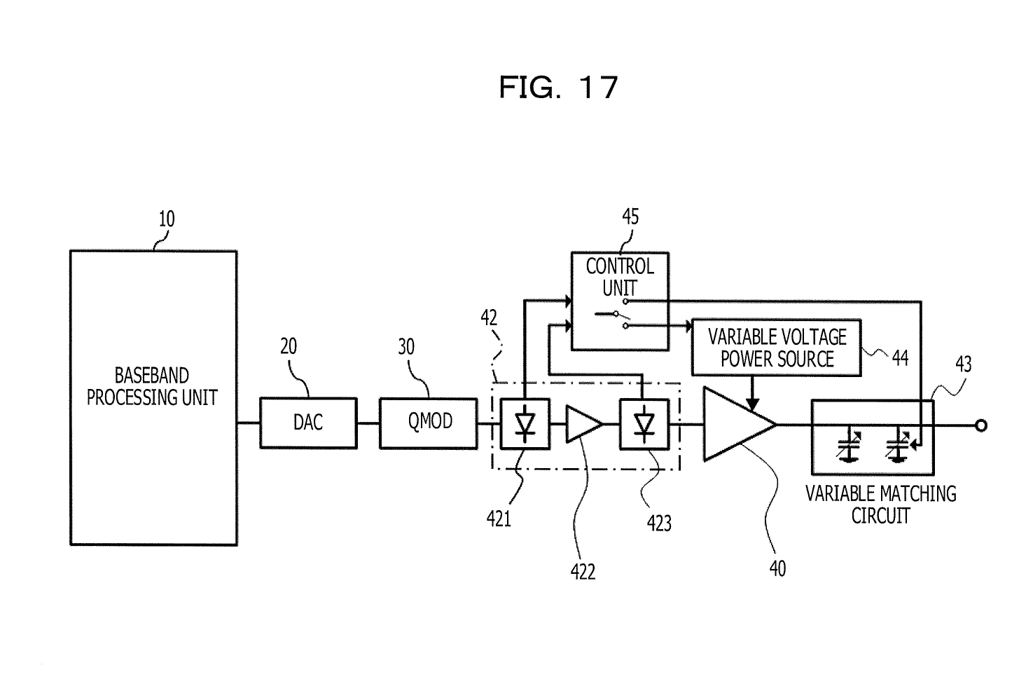

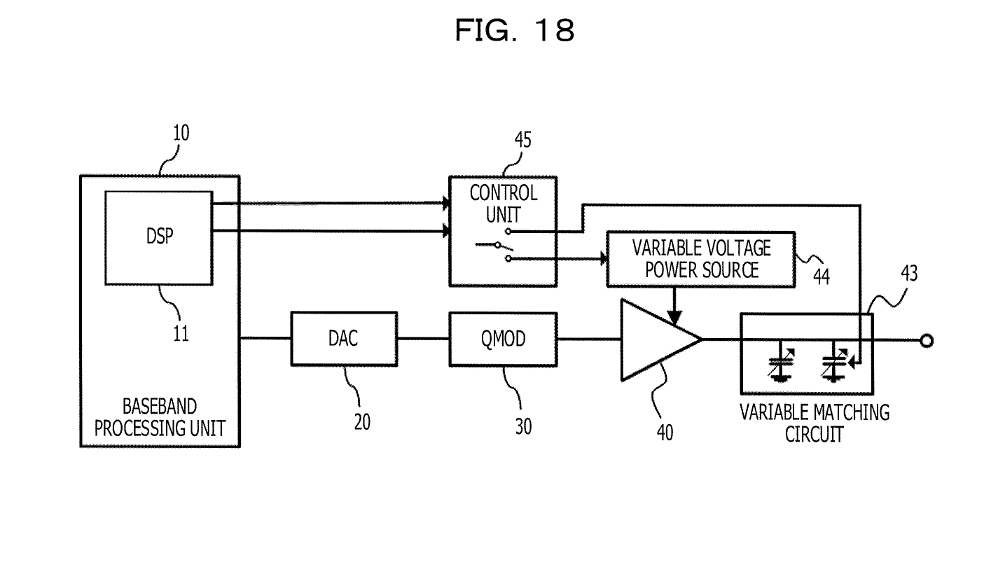

FIGS. 17 and 18 illustrate an example of a power amplifier. As illustrated in FIG. 17, the limiter function unit 42 may also be a driver amplifier 422 having a limiter function (hereinafter, may also be referred to as a “limiter amplifier”). The limiter function unit 42 may be a digital signal processor (DSP) 11 equipped in the baseband processing unit 10 as illustrated in FIG. 18. The DSP 11 may be one example of a digital signal processing circuit. Limitation (limiter operation) of a high frequency signal level input to the PA 40 may also be achieved in analog and may also be achieved digitally.

In FIG. 17, amplitude detectors 421 and 423 are equipped on respective input and output sides of the limiter amplifier 422 to supply the envelope detected by the respective amplitude detectors 421 and 423 to the control unit 45. The amplitude detectors 421 and 423 may correspond to the amplitude detection unit 41. The control unit 45 may determine whether or not the limiter function operates by the envelope of an input/output signal of the limiter amplifier 422.

In FIG. 18, the DSP 11 detects an envelope of an input signal to the PA 40 to supply the envelope and the limiter operation notification from the DSP 11 to the control unit 45.

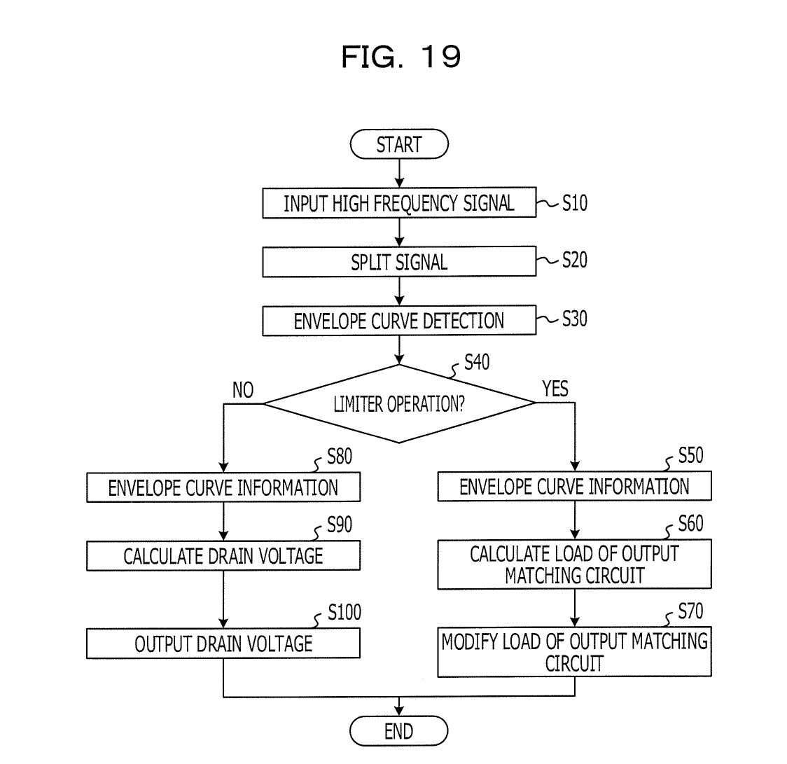

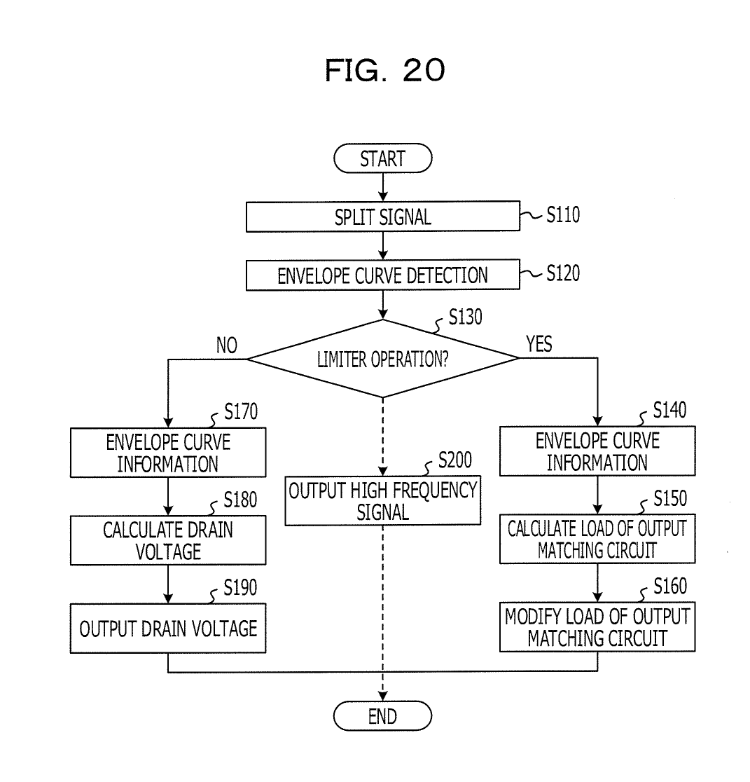

FIGS. 19 and 20 illustrate an example of power control. The power control illustrated in FIG. 19 indicates power control operation in the power amplifier illustrated in FIG. 17. The power control illustrated in FIG. 20 indicates power control operation in the power amplifier illustrated in FIG. 18.

As illustrated in FIG. 19, in a case that the driver amplifier 422 has a limiter function, a high frequency signal is input from the QMOD 30 (operation S10). The high frequency signal is split, through the respective amplitude detectors 421 and 423, into a route to be output to the control unit 45 and a route to be output to the PA 40 (operation S20).

In the respective amplitude detectors 421 and 423, an envelope of the input high frequency signal is detected by envelope curve detection to give the detected envelope to the control unit 45 (operation S30). The control unit 45 determines whether or not the limiter amplifier 422 operates as a limiter (operation S40).

When the limiter amplifier 422 operates as a limiter (a case of YES in operation S40), the control unit 45 calculates load of the variable matching circuit 43 based on the envelope given from the respective amplitude detectors 421 and 423 (operations S50 and S60). The control unit 45 controls (modifies) the load of the variable matching circuit 43 in accordance with the calculation result (operation S70).

When the limiter amplifier 422 does not operate as a limiter (a case of NO in operation S40), the control unit 45 calculates a drain voltage of the PA 40 based on the envelope given from the respective amplitude detectors 421 and 423 (operations S80 and S90). The control unit 45 controls an output voltage (drain voltage) of the variable voltage source in accordance with the calculation result (operation S100).

As illustrated in FIG. 20, in a case that the baseband processing unit 10 has a limiter function, a part of the output signal to the PA 40 is split into the DSP 11 (operation S110) and envelope curve detection is carried out in the DSP 11 (operation S120). An envelope obtained by the envelope curve detection and limiter operation notification based on the envelope are given to the control unit 45.

When the limiter operation notification is given from the DSP 11 (a case of YES in operation S130), the control unit 45 calculates load of the variable matching circuit 43 based on the envelope given from the DSP 11 (operations S140 and S150). The load of the variable matching circuit 43 is controlled (modified) in accordance with the calculation result (operation S160).

When the limiter amplifier operation notification is not given from the DSP 11 (a case of NO in operation S130), the control unit 45 calculates a drain voltage of the PA 40 based on the envelope given from the DSP 11 (operations S170 and S180). The output voltage (drain voltage) of the variable voltage source 44 is controlled in accordance with the calculation result (operation S190).

In operation S200, regardless of the presence of limiter operation notification, a high frequency signal is output from the baseband processing unit 10 through the DAC 20 and the QMOD 30 to the PA 40.

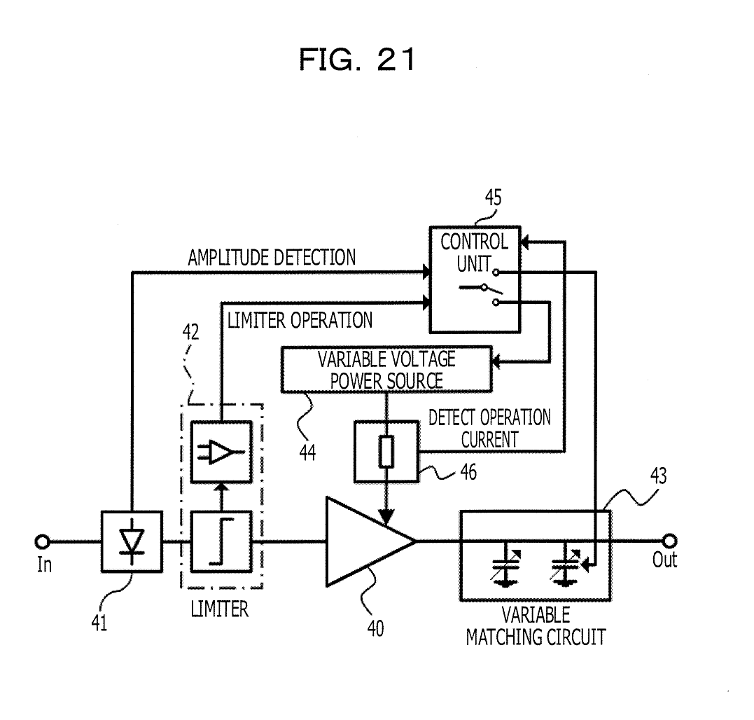

FIG. 21 illustrates an example of a power amplifier. To the power amplifier illustrated in FIG. 21, an operation current detection unit 46 to detect a drain current (operation current) given to the PA 40 from the variable voltage source 44 is added in comparison with the configuration illustrated in FIG. 9. In FIG. 21, other elements may substantially be same as or similar to the elements illustrated in FIG. 9.

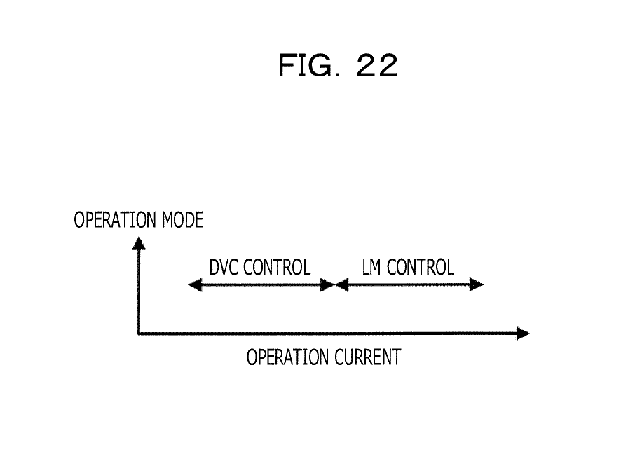

The result of detection by the operation current detection unit 46 is given to the control unit 45. FIG. 22 illustrates an example of current control. The control unit 45 switches between DVC and LM control in accordance with the operation current as illustrated in, for example, FIG. 22. The switching control based on an operation current may be given priority over switching control based on limiter operation notification. While a diode is used for the envelope detection, one resistor is used for current detection, so that the configuration may be simplified.

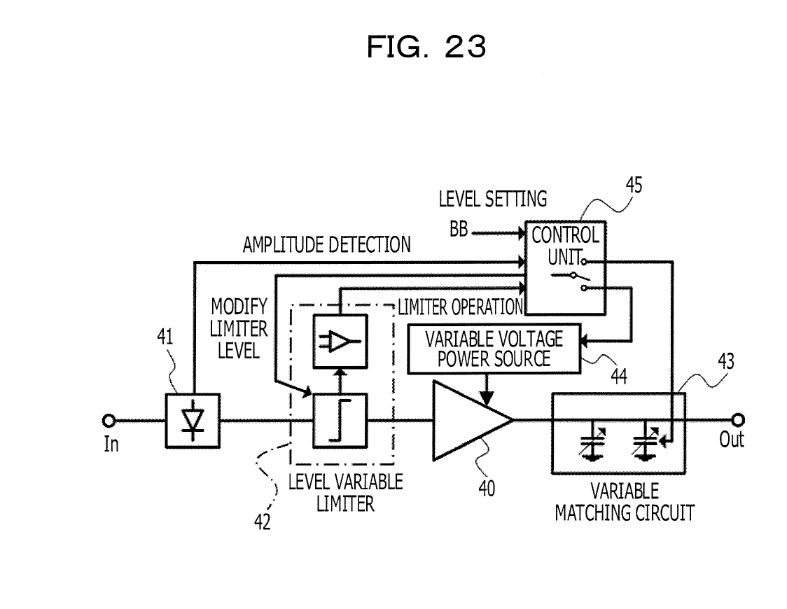

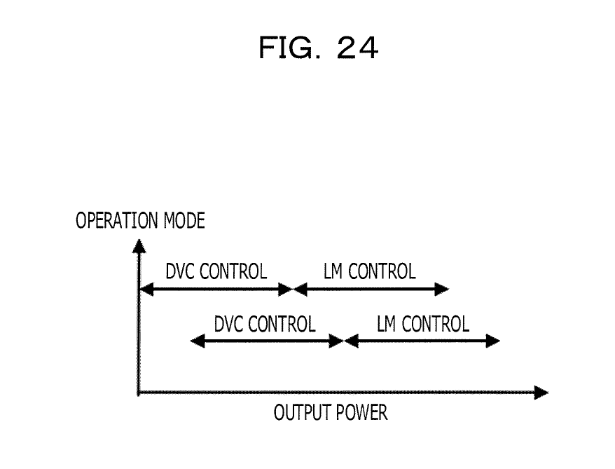

FIG. 23 illustrates an example of a power amplifier. FIG. 24 illustrates an example of voltage control. In a limiter function unit, as illustrated in FIG. 23, the limiter level may be variable in accordance with control from the control unit 45. The limiter level is modified, thereby modifying a switching point between DVC and LM control as illustrated in, for example, FIG. 24. The power amplifier illustrated in FIG. 23 may be used for a software radio that allows system modification.

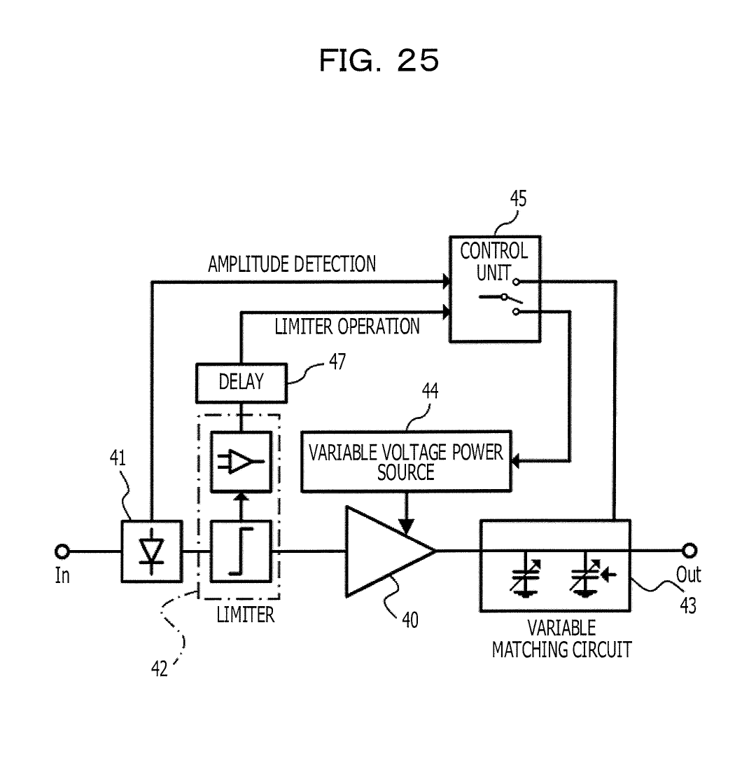

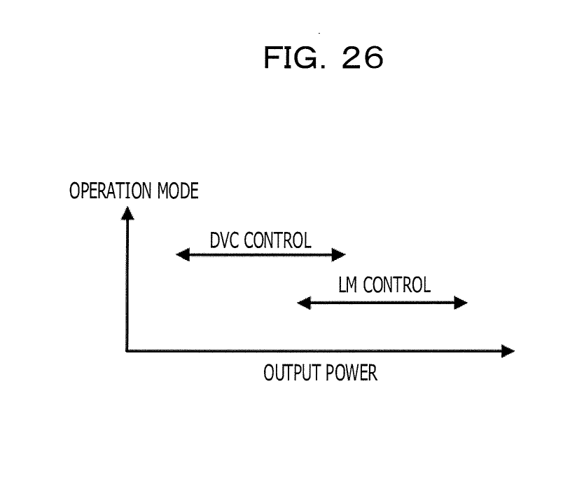

FIG. 25 illustrates an example of a power amplifier. FIG. 26 illustrates an example of voltage control. As illustrated in FIG. 25, a delay circuit 47 may also be equipped between the limiter function unit 42 and the control unit 45 to give a delay to limiter operation notification that is to be given to the control unit 45 (the limiter detection signal may also be delayed). A delay is given to limiter operation notification, thereby partially overlapping DVC and LM control as illustrated in, for example, FIG. 26.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiments of the present invention have been described in detail, it should be understood that the various changes, substitutions, and alterations could be made hereto without departing from the spirit and scope of the invention.

What is claimed is:

1. A control device of a power amplifier comprising:
a limiter configured to limit a level of an input signal to the power amplifier; and
a control unit configured to, when the limiter operates, make an operation voltage of the power amplifier invariable and control load of an output matching circuit of the power amplifier based on an amplitude of the input signal, and, when the limiter does not operate, to make the load of the output matching circuit invariable and control the operation voltage of the power amplifier.

2. The control device according to claim 1, wherein the limiter is a driver amplifier having a limiter function provided prior to the power amplifier.

3. The control device according to claim 2, wherein the amplitude of the input signal is detected by an amplitude detector equipped on input and output sides of the driver amplifier.

4. The control device according to claim 1, wherein the limiter is a digital signal processing circuit provided in a baseband processing unit that baseband-signal-processes the input signal.

5. The control device according to claim 4, wherein the amplitude of the input signal is detected in the baseband signal processing by the digital signal processing circuit.

6. The control device according to claim 1, wherein the control unit controls the operation voltage so as to make input and output characteristics of the power amplifier linear when the limiter does not operate.

7. The control device according to claim 1, further comprising:
an operation current detection unit configured to detect an operation current of the power amplifier,
wherein the control unit switches between control of the load and control of the operation voltage based on the operation current detected by the operation current detection unit.

8. The control device according to claim 1, wherein the control unit variably controls the level at which the limiter limits the input signal.

9. The control device according to claim 1, further comprising:
a delay circuit configured to temporally delay limiter notification that indicates whether or not the limiter is during an operation to the control unit.

10. A method of controlling a power amplifier comprising:
limiting a level of an input signal to a power amplifier by a limiter;
making, when the limiter operates, an operation voltage of the power amplifier invariable and controlling load of an output matching circuit of the power amplifier based on an amplitude of the input signal; and
making, when the limiter does not operate, the load of the output matching circuit invariable and controlling the operation voltage of the power amplifier.

11. The method according to claim 10, further comprising,
detecting the amplitude of the input signal by an amplitude detector.

12. The method according to claim 10, further comprising,
detecting the amplitude of the input signal by an amplitude detector equipped on input and output sides of the power amplifier.

13. The method according to claim 10, further comprising,
detecting the amplitude of the input signal in a baseband signal processing by a digital signal processing circuit.

14. The method according to claim 10, further comprising,
controlling the operation voltage so as to make input and output characteristics of the power amplifier linear when the limiter does not operate.

15. The method according to claim 10, further comprising:
detecting an operation current of the power amplifier; and
switching between control of the load and control of the operation voltage based on the operation current.

16. The method according to claim 10, further comprising,
controlling variably the level at which the limiter limits the input signal.

17. The method according to claim 10, further comprising:
delaying temporally delay limiter notification that indicates whether or not the limiter is during an operation to the control unit.
